(19) United States
(12) Patent Application Publication
(10) Pub. No.: US 2009/0091251 A1
(43) Pub. Date: Apr. 9, 2009

(54) ORGANIC EL DEVICE

(75) Inventors: Hajime Nakanotani, Higashi-ku (JP); Chihaya Adachi, Higashi-ku (JP); Masato Moriwake, Kyoto-shi (JP)

Correspondence Address: FISH & RICHARDSON P.C., P.O. BOX 1022, MINNEAPOLIS, MN, 55440-1022, US

(73) Assignees: Kyushu University, National University Corporation, Fukuoka (JP); Rohm Co., Ltd., Kyoto (JP)

(21) Appl. No.: 12/201,163

(22) Filed: Aug. 29, 2008

(30) Foreign Application Priority Data
Aug. 31, 2007 (JP) 2007-225993

(51) Int. Cl. H01J 1/62

(52) U.S. Cl. 313/504

(57) ABSTRACT

An organic EL device including a substrate, a positive electrode layer, a first organic layer containing a first organic light-emitting material, a negative electrode layer made of metal, and a second organic layer containing a second organic light-emitting material capable of emitting light by absorbing at least a part of light emitted from the first organic light-emitting material, in this order is provided. The negative electrode layer preferably includes a layer made of Ag.

### BACKGROUND OF THE INVENTION

1. Field of the Invention

The present invention relates to an organic EL device, and more specifically to a top emission type EL device utilizing a plasmon resonance phenomenon.

2. Description of the Background Art

Organic EL devices (organic electroluminescence devices) are actively researched and developed as display devices of the next generation, and have been partly brought into practice. Organic EL devices are largely classified into a top emission type and a bottom emission type. The top emission type is an organic EL device in which light is taken out from the side opposite to the substrate, and in the bottom emission type organic EL device, light is taken out from the side of the substrate.

In a top emission type organic EL device, in order to take out light from the side opposite to the substrate, generally the electrode on the side of the substrate is composed of a reflecting electrode, and the electrode on the side opposite to the substrate is composed of a transparent electrode (for example, Japanese Patent Laying-Open No. 2006-004721). On the other hand, in the bottom emission type organic EL device, in order to take out light form the side of the substrate, generally, the electrode on the side of the substrate is composed of a transparent electrode and the electrode on the side opposite to the substrate is composed of a reflecting electrode. As an electrode (negative electrode) on the side opposite to the substrate in a bottom emission type organic EL device, an opaque electrode made of metal is generally used.

Therefore, in the bottom emission type organic EL device, it is believed that light is difficult to be taken out from the side of the negative electrode because opaque metal is used as the negative electrode.

By the way, P. Andrew and W. L. Barnes, Science Vol. 306 (2004) p. 1002 describes that energy transfer occurs between organic pigment molecules via a surface plasmon on a metal thin-film surface.

### SUMMARY OF THE INVENTION

It is an object of the present invention to provide an organic EL device using a negative electrode made of metal, in which emitted light is taken out from the side of the negative electrode.

The present invention provides an organic EL device including a substrate, a positive electrode layer, a first organic layer containing a first organic light-emitting material, a negative electrode layer made of metal, and a second organic layer containing a second organic light-emitting material capable of emitting light by absorbing at least a part of light emitted from the first organic light-emitting material in this order.

Here, the negative electrode layer preferably includes a layer made of Ag. The negative electrode layer may have a laminate structure made up of a layer made of Ca, MgAu or MgAg and a layer made of Ag. A thickness of the negative electrode layer is preferably 40 to 120 nm.

The positive electrode layer may be composed of a transparent electrode, or of a reflecting electrode. In the organic EL device of the present invention, a peak wavelength of the light taken out from the side of the second organic layer is equal to or longer than the peak wavelength of light taken out from the side of the substrate.

According to the present invention, such a revolutionary top emission type organic EL device in which emitted light is taken out from the side of the negative electrode made of metal is provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic section view showing one preferred example of an organic EL device of the present invention.

FIG. 2 represents emission spectrum of Alq₃, emission spectrum of DCM and absorption spectrum of DCM.

FIG. 3 represents EL spectra of lights emitted from a positive electrode side and a negative electrode side in an organic EL device of Example 1.

FIG. 4 is a view showing change in EL spectrum of light emitted from the negative electrode side with varying a thickness of a negative electrode layer.

FIG. 5 is a view showing a relationship between a thickness of a negative electrode layer, and a ratio of emission intensity from DCM, with respect to emission intensity from Alq₃ in the light emitted from the side of the negative electrode layer.

FIG. 6 is a view showing change in EL spectrum of light emitted from the negative electrode side with varying a thickness of a light-emitting/electron transport layer.

FIG. 7 is a view showing change in EL spectrum of light emitted from the negative electrode side with different kinds of the negative electrode layer.

FIG. 8 is an EL spectrum of light emitted from the negative electrode side in an organic EL device of Example 5.

### DESCRIPTION OF THE PREFERRED EMBODIMENTS

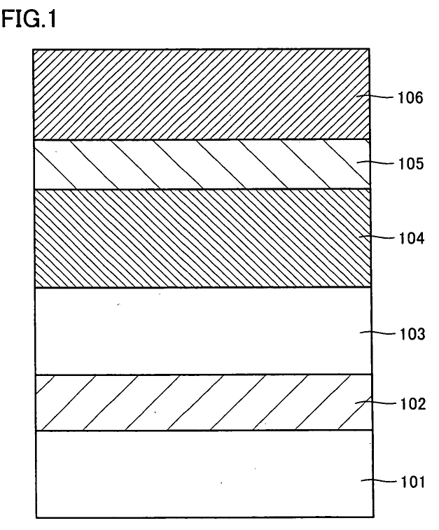

In the following, the present invention will be described more specifically. FIG. 1 is a schematic section view showing a preferred one example of an organic EL device of the present invention. The organic EL device shown in FIG. 1 includes a substrate 101, a positive electrode layer 102, a hole transport layer 103, a first organic layer 104 which is a light-emitting/electron transport layer, a negative electrode layer 105 and a second organic layer 106 stacked in this order. Specifically, the organic EL device of the present invention includes a structure of sandwiching the negative electrode layer with the first organic layer and the second organic layer.

First organic layer 104 which is a light-emitting/electron transport layer contains a first organic light-emitting material. Second organic layer 106 contains a second organic light-emitting material capable of emitting light by absorbing at least a part of the light emitted from the first organic light-emitting material. In the present invention, light emission from second organic layer 106 is observed as a result of occurrence of long-distance energy transfer via surface plasmon of the surface of negative electrode layer 105 from the first organic light-emitting material (doner) to the second organic light-emitting material (acceptor). Here, since energy transfer via the surface plasmon also occurs when the transfer distance exceeds a critical distance of Forster-type energy transfer, the thickness of negative electrode layer 105 may be equal to or more than the Forster transfer distance.

Energy transfer by the Forster-type energy transfer (dipole-dipole interaction) occurs by resonance between a transition dipole from excitation state to ground state of a doner molecule, and a transition dipole from ground state to transition state of an acceptor molecule. In order to improve the energy transfer efficiency from the doner molecule to the acceptor molecule, it is necessary to make the overlap between emission spectrum of the doner molecule and absorption spectrum of the acceptor molecule large, and to make the distance between the doner molecule and the acceptor molecule short. In the Forster type energy transfer, it is not necessary for molecules to collide with each other for energy transfer, and energy transfer occurs even when the intermolecular distance is about 1 to 10 nm.

As described above, in order to make energy transfer from first organic layer 104 to second organic layer 106 occur by the Forster-type energy transfer, it is necessary that a thickness of negative electrode layer 105 is 1 to 10 nm, however, the thickness of negative electrode layer 105 from 1 to 10 nm may cause deterioration in characteristics of the device. On the other hand, since energy transfer via surface plasmon according to the present invention also occurs when the transfer distance exceeds critical distance (1 to 10 nm) of the Forster-type energy transfer, a stable device characteristic can be obtained.

In the following, detailed description will be given for each layer.

The first organic light-emitting material (doner) used in first organic layer 104 may be a conventionally known organic light-emitting material used in an organic EL device. As such an organic light-emitting material, for example, tris(8-hydroxyquinoline)aluminum (hereinafter, also referred to as Alq₃), 4,4′-bis(2,2-diphenylvinyl)biphenyl (DPVBi), 4,4′-bis[2-{4-(N,N-diphenylamino) phenyl}vinyl]biphenyl (DPAVBi), Ir(ppy)₃, CBP and so on may be recited. Thickness of first organic layer 104 is not particularly limited, and may be a thickness commonly employed in an organic EL device (for example, about 10 to 100 nm, preferably about 10 to 50 nm), however, a thickness of the first organic layer may influence on intensity of light emitted from the second organic layer. Therefore, it is preferred to adjust the thickness of the first organic layer depending on the kinds of the first and the second organic light-emitting materials so that emission intensity from the second organic layer (luminescence from the side of the negative electrode layer) is large.

As the second organic light-emitting material (acceptor) capable of emitting light by absorbing at least a part of the light emitted from the first organic light-emitting material, for example, 4-(dicyanomethylene)-2-methyl-6-(p-dimethylaminostyryl)-4H-pyran (hereinafter, also referred to as DCM), rhodamine 6G, DCM2, DCJTB, Btp₂Ir (acac), PQ₂Ir (acac) and the like can be recited. Thickness of second organic layer 106 is not particularly limited, and for example, may be about 10 to 100 nm. In the first organic layer and the second organic layer, the first and the second organic light-emitting materials may be respectively present as a dopant contained in a host material.

For negative electrode layer 105, metal that is able to cause surface plasmon resonance by coupling between surface plasmon localized on the surface of the negative electrode layer and the light emitted from first organic layer 104 is used. As such metal, Ag, Au, Al and the like can be recited. Negative electrode layer 105 may consist of a layer made of Ag, Au or the like, or may consist of a laminate structure of two or more layers using different metals. Concrete examples of the laminate structure include Ca layer/Ag layer, MgAg layer/Ag layer, MgAu layer/Ag layer, LiF layer/Ag layer and so on. In the recited laminate structures, the layer provided between first organic layer 104 and the Ag layer, such as Ca layer, MgAg layer or the like can change surface shape (surface roughness or the like) in a boundary between first organic layer 104 and negative electrode layer 105, thereby improving intensity of the light emitted from second organic layer 106.

Thickness of negative electrode layer 105 is not particularly limited, but may be about 5 to 200 nm. Thickness of negative electrode layer 105 influences on intensity of the light emitted from second organic layer 106. Therefore, from the view point of emission intensity, a thickness of negative electrode layer 105 is preferably not less than 40 nm and not more than 120 nm.

Between positive electrode layer 102 and negative electrode layer 105, a hole injection layer, a hole transport layer, an electron injection layer and the like may be additionally provided. In the above embodiments, the case where the first organic layer is a light-emitting/electron transport layer is exemplified, however, the light-emitting layer and the electron transport layer may be separate layers, and also in this case, the first organic layer represents a light-emitting layer.

Positive electrode layer 102 may be a transparent electrode of ITO (indium-tin oxide), IZO (indium-zinc oxide), ZnO (zinc oxide) or the like. Thickness is, for example, but is not particularly limited to about 30 to 150 nm. By implementing the positive electrode layer by a transparent electrode, it is possible to obtain an organic EL device capable of taking out light both from the substrate side and from the second organic layer side. On the other hand, when positive electrode layer 102 is composed of an electrode of opaque metal such as Al, Ag, MgAu and the like, it is possible to obtain an organic EL device capable of taking out light only from the second organic layer side. Alternatively, an organic EL device emitting light only from the side of the second organic layer can be obtained also by implementing the positive electrode layer by a transparent electrode, and providing a reflecting layer of metal between the positive electrode layer and the substrate.

Examples of substrate 101 include, but are not particularly limited to, transparent substrates such as glass substrate and plastic substrate, and opaque substrates such as Si, SiO₂, TiO₂, SiO₂/TiO₂ dielectric multilayer substrates. When light is taken out also from the side of the positive electrode, a transparent substrate is used.

According to the organic EL device of the present invention, by applying a transparent electrode as the positive electrode layer, it is possible to take out light emitted from the first organic layer from the side of the positive electrode layer (substrate side), and to take out light also from the side of the second organic layer (negative electrode side) by energy transfer via surface plasmon. A peak wavelength of light emitted from the second organic layer is equal to or longer than a peak wavelength of light emitted from the first organic layer taken out from the positive electrode side. That is, according to the organic EL device of the present invention, it is possible to take out light having a different wavelength from the light taken out from the positive electrode side, from the negative electrode side. Also in a bottom emission type organic EL device using a negative electrode of metal, light loss by light absorption or plasmon absorption at the negative electrode is conventionally problematic, however, in the organic EL device of the present invention, since at least a part of the light absorbed in the negative electrode contributes to light emission from the second organic layer, it is possible to utilize the light from the first organic layer more effectively.

In the following, the present invention will be described in more detail by way of examples, however, the present invention is not limited to these.

### EXAMPLE 1

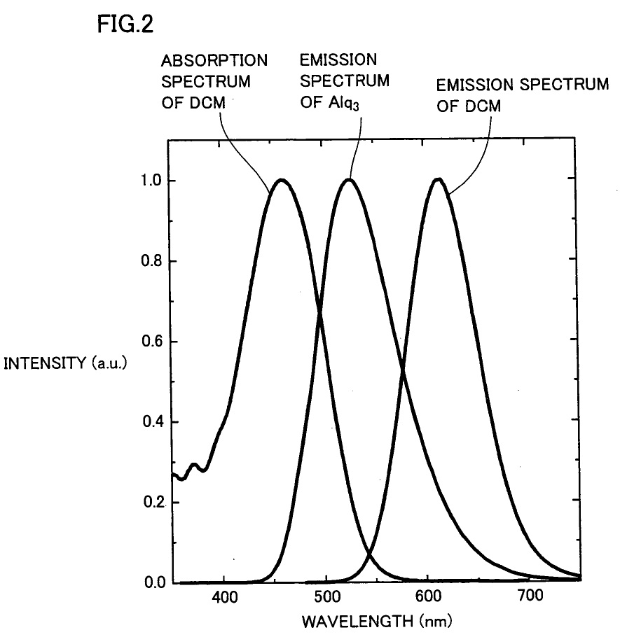

On a glass substrate on which an ITO electrode (thickness 110 nm) is formed, 50 nm of α-NPD (4,4′-bis[N-(1-naphthyl)-N-phenyl-amino]biphenyl) as a hole transport layer, and 30 nm of Alq₃ as a light-emitting/electron transport layer (first organic layer) were vapor deposited by a vacuum vapor depositing method, and then 80 nm of an Ag electrode as a negative electrode layer was formed. Then, as a second organic layer, 80 nm of 1 mol %-DCM/Alq₃ layer was vapor deposited, to produce an organic EL device having the structure as shown in FIG. 1. FIG. 2 shows emission spectrum of Alq₃, emission spectrum of DCM, and absorption spectrum of DCM (intensity is standardized).

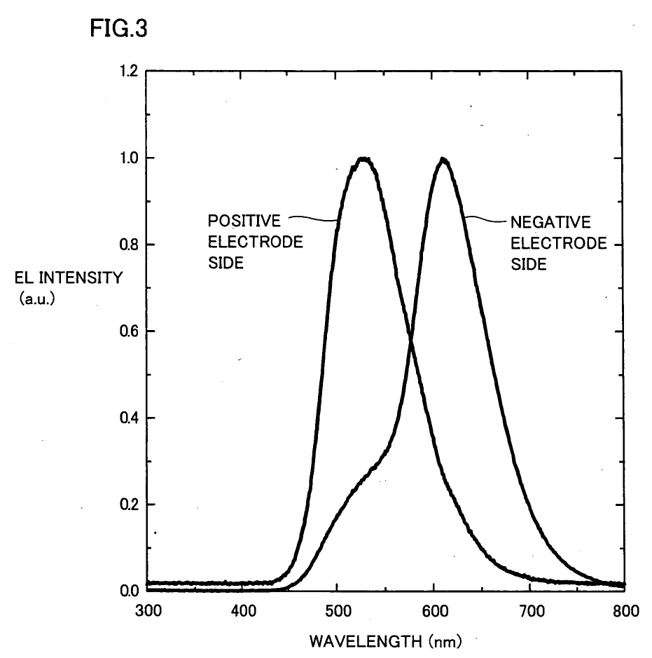

FIG. 3 shows EL spectra of lights emitted from the positive electrode side and the negative electrode side at a current density of 100 mA/cm². EL intensity is standardized so that the maximum value is 1. As shown in FIG. 3, light emission (peak wavelength 520 nm) of only Alq₃ was observed from the positive electrode side, while light emission (peak wavelength 610 nm) from the DCM was observed from the negative electrode side.

### EXAMPLE 2

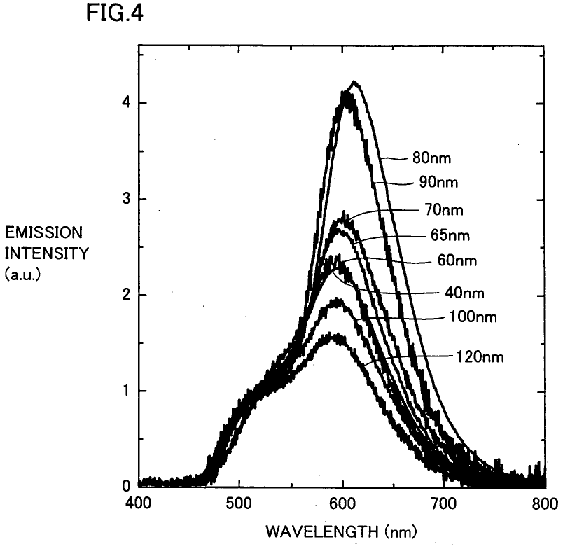

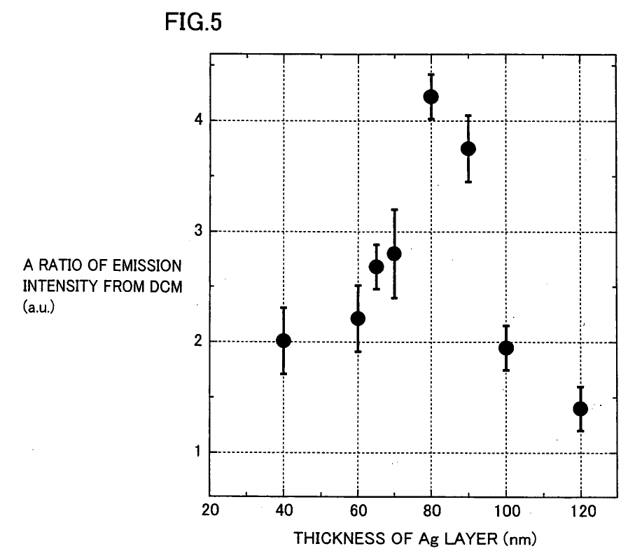

Organic EL devices were fabricated in the same manner as in Example 1 except that a thickness of the negative electrode layer (Ag layer) was 40, 60, 65, 70, 90, 100 or 120 nm, and EL spectrum of light emitted from the negative electrode side (second organic layer side) was measured (current density 100 mA/cm²). The results are shown in FIG. 4 (each EL spectrum is standardized at 520 nm). Further, FIG. 5 is a view showing a relationship between a thickness of a negative electrode layer, and a ratio of emission intensity from DCM, with respect to emission intensity from Alq₃ in the light emitted from the negative electrode side. As shown in FIG. 4 and FIG. 5, it can be found that emission intensity from DCM peaks when a thickness of a negative electrode layer is 80 to 90 nm.

### EXAMPLE 3

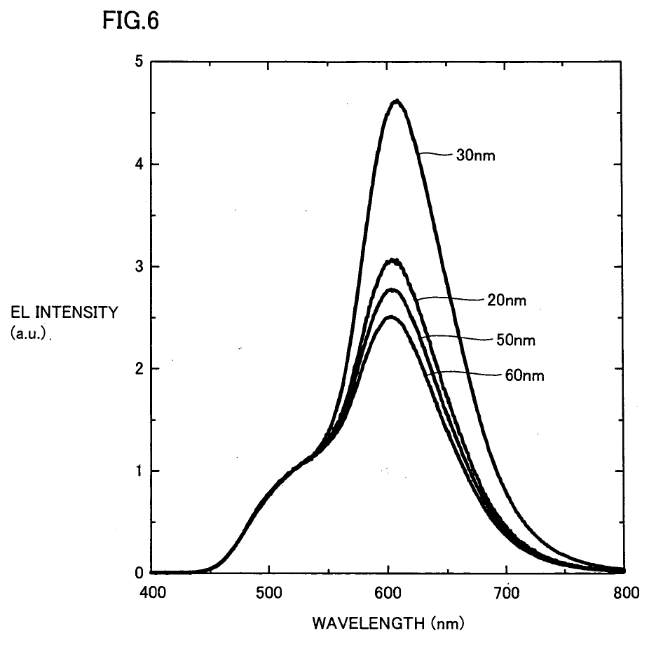

Organic EL devices were fabricated in the same manner as in Example 1 except that a thickness of the light-emitting/electron transport layer (first organic layer) was 20, 50 or 60 nm, and EL spectrum of light emitted from the negative electrode side (second organic layer side) was measured (current density 100 mA/cm²). The results are shown in FIG. 6 (each EL spectrum is standardized at 520 nm). As shown in FIG. 6, it can be found that emission intensity from DCM peaks when a thickness of an Alq₃ layer (first organic layer) is 30 nm.

### EXAMPLE 4

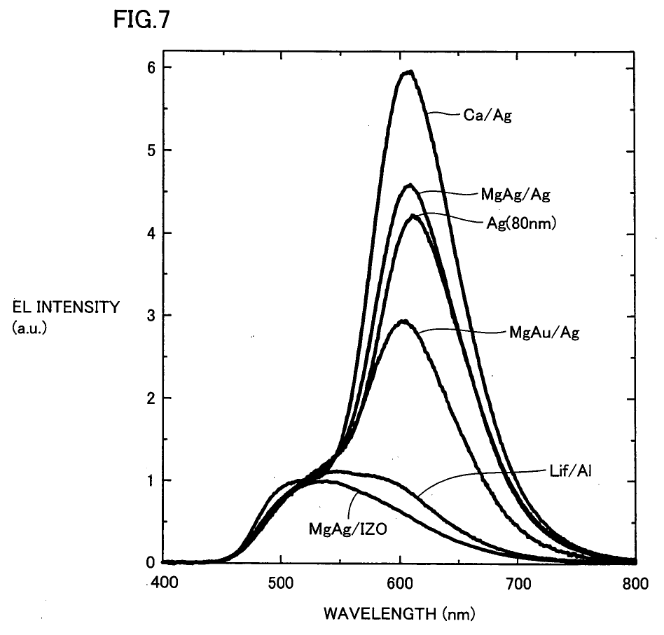

Organic EL devices were fabricated in the same manner as in Example 1 except that the negative electrode layer was a laminate structure of Ca (5 nm)/Ag (75 nm), MgAg (5 nm)/Ag (75 nm), MgAu (5 nm)/Ag (75 nm), LiF (0.5 nm)/Al (80 nm) or MgAg (5 nm)/IZO (40 nm), and EL spectrum of light emitted from the negative electrode side (second organic layer side) was measured (current density 100 mA/cm²). The results are shown in FIG. 7 (each EL spectrum is standardized at 520 nm). As shown in FIG. 7, it was found that EL emission intensity from the negative electrodes side increases when negative electrode layer consisting of Ca (5 nm)/Ag (75 nm) or MgAg (5 nm)/Ag (75 nm) was used, in comparison with the case where Ag monolayer (80 nm) was used as in Example 1. Maximum external quantum efficiencies observed from the negative electrode side in organic EL devices using the negative electrode layers consisting of Ca (5 nm)/Ag (75 nm) and MgAg (5 nm)/Ag (75 nm) were about 0.05% and 0.02%, respectively Further, the weak light emission from DCM observed when the negative electrode layer has LiF/Al or MgAg/IZO reveals that Ag is a metal useful for long-distance energy transfer via surface plasmon. Improvement in EL intensity of light emitted from the negative electrode side observed when the negative electrode layers consisting of Ca/Ag and MgAg/Ag are used, is partly attributable to the fact that surface plasmon resonance is promoted as the surface ruggedness cycle is increased in the boundary of light-emitting/electron transport layer (Alq₃ layer)-negative electrode layer.

### EXAMPLE 5

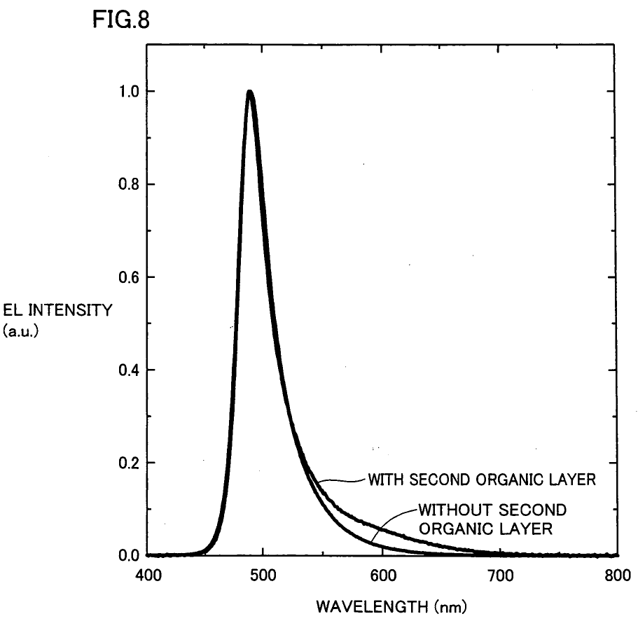

Organic EL devices were fabricated in the same manner as in Example 1 except that the negative electrode layer consisted of MgAg (5 nm)/Ag (75 nm), the positive electrode layer consisted of Al (80 nm)/MoO₃(10 nm) (Al layer on the substrate side), and the substrate was a Si/SiO₂ substrate, and EL spectrum of light emitted from the negative electrode side (second organic layer side) was measured (current density 100 mA/cm²). The results are shown in FIG. 8. EL spectrum of light emitted from the negative electrode side in the organic EL device not having a second organic layer is also shown together for comparison. As shown in FIG. 8, in the organic EL device having a second organic layer, light emission from DCM is also observed although it is weak.

Although the present invention has been described and illustrated in detail, it is clearly understood that the same is by way of illustration and examples only and is not to be taken by way of limitation, the scope of the present invention being interpreted by the terms of the appended claims.

What is claimed is:

1. An organic EL device comprising:
a substrate;
a positive electrode layer;
a first organic layer containing a first organic light-emitting material;
a negative electrode layer made of metal; and
a second organic layer containing a second organic light-emitting material capable of emitting light by absorbing at least a part of light emitted from said first organic light-emitting material, in this order.

2. The organic EL device according to claim 1, wherein said negative electrode layer includes a layer made of Ag.

3. The organic EL device according to claim 2, wherein said negative electrode layer has a laminate structure made up of a layer made of Ca, MgAu or MgAg, and a layer made of Ag.

4. The organic EL device according to claim 1, wherein a thickness of said negative electrode layer is 40 to 120 nm.

5. The organic EL device according to claim 1, wherein said positive electrode layer is composed of a transparent electrode.

6. The organic EL device according to claim 1, wherein said positive electrode layer is composed of a reflecting electrode.

7. The organic EL device according to claim 1, wherein a peak wavelength of the light taken out from the side of said second organic layer is equal to or longer than a peak wavelength of light taken from the side of said substrate.
